(19) United States
(12) Patent Application Publication
(10) Pub. No.: US 2025/0167132 A1
(43) Pub. Date: May 22, 2025

(54) NOVEL METHOD OF EMI SHIELDING

(71) Applicants: Applied Materials, Inc., Santa Clara, CA (US); The Florida International University Board of Trustees, Miami, FL (US)

(72) Inventors: Ghaleb Saleh Ghaleb Al-Duhni, Miami, FL (US); Mudit Sunilkumar Khasgiwala, Milpitas, CA (US); Markondeyaraj Pulugurtha, Miami, FL (US); Satheesh Bojja Venkatakrishnan, Miami, FL (US); John Leonidas Volakis, Miami, FL (US); Subramani Kengeri, Saratoga, CA (US); Kunal Ghosh, Bengaluru (IN); Meghna Maheshkumar Patel, Navsari (IN); Sachin Jayant Patil, Bengaluru (IN); Arvin Khosravi, Los Gatos, CA (US)

(73) Assignees: Applied Materials, Inc., Santa Clara, CA (US); The Florida International University Board of Trustees, Miami, FL (US)

(21) Appl. No.: 18/512,439

(22) Filed: Nov. 17, 2023

(51) Int. Cl. H01L 23/552; H01L 23/13

(52) U.S. Cl. CPC H01L 23/552; H01L 23/13

(57) ABSTRACT

A shielding structure for a semiconductor device may include a first segment formed from a first set of layers including a first metal and a second metal. The structure may include a second segment formed from a second set of layers. The second set of layers may include the first metal and the second metal, the second segment orthogonal to the first segment, where the second segment is configured to be inserted into a trench in a substrate of the semiconductor device.

### TECHNICAL FIELD

The present technology relates to semiconductor systems, processes, and equipment. More specifically, the present technology relates to shielding electromagnetic fields for preserving system functions, providing security and meeting compatibility requirements.

### BACKGROUND

Electromagnetic interference (EMI) shielding has been a major concern with high-density computing and communication systems (e.g., advanced packages and other semiconductor devices). The dense integration of heterogeneous components may amplify these concerns, as the EMI generated by the components may affect other components more due to the increased density of components within the package.

### BRIEF SUMMARY

A semiconductor device may include a substrate may include at least one trench. The device may include a component, where the component requires shielding from electromagnetic signals. The device may include a shielding structure inserted in the at least one trench.

In some embodiments, the shielding structure shields the component from electromagnetic signals. The shielding structure may extend through the trench and is electrically connected to a ground of the semiconductor device. The shielding structure may be bonded to the ground using a solder paste, a metal paste, or a silver paste. The shielding structure may include a single metal layer, the single metal layer may include at least one of copper, nickel, iron, cobalt, and silver. The shielding structure may include magnetic conducting layers and nonmagnetic conducting layers.

In some embodiments, the shielding structure may include 2 nonmagnetic conducting layers and 2 magnetic conducting layers. The shielding structure may include 2 nonmagnetic conducting layers and 3 magnetic conducting layers or may include 3 nonmagnetic conducting layers and 2 magnetic conducting layers. The total thickness of the shielding structure may be about 5 microns. The shielding structure may include two or more metal layers, each of the two or more metal layers may include at least one of copper, nickel, iron, cobalt, and silver. The shielding structure may include a T-shape, where a bottom segment of the shielding structure is inserted into the trench, and a vertical segment of the shielding structure extends on opposite sides of the trench.

A shielding structure for a semiconductor device may include a first segment formed from a first set of layers including a first metal and a second metal. The structure may include a second segment formed from a second set of layers. The second set of layers may include the first metal and the second metal, the second segment orthogonal to the first segment, where the second segment is configured to be inserted into a trench in a substrate of the semiconductor device.

In some embodiments, the trench may include a magnetic material on one or more walls of the trench, the magnetic material extending from a surface of the substrate to a metal layer of the semiconductor device. The first segment may be configured to shield an electronic device from electromagnetic interference from a first direction, and the second segment is configured to shield an electronic device from electromagnetic interference from a second direction.

A method of forming shielding structures for semiconductor packages may include providing a carrier substrate. The method may include depositing a first metal layer on the carrier substrate to a first thickness. The method may include depositing a second metal layer on the first metal layer to a second thickness. The method may include removing the carrier substrate from the first metal layer to form a sheet of shielding material. The method may include separating the sheet of shielding material into two or more segments. The method may include attaching each of the two or more segments in to form a shielding structure. The method may inserting the shielding structure into a trench disposed in a substrate of a semiconductor package.

In some embodiments, the first thickness and the second thickness are about 2 micrometers to about 5 micrometers. The shielding structure may include a l-shape where at least one vertical segment is inserted into the trench of the substrate. The first thickness and the second thickness may form a total thickness of between about 5 and about 50 micrometers. Prior to inserting the shielding structure, the trench disposed in the substrate of the semiconductor package may be filled with a conducting paste may include silver and/or graphene.

### BRIEF DESCRIPTION OF THE DRAWINGS

FIG. 1 illustrates a device with a component to be shielded, according to certain embodiments.

FIG. 2 illustrates a flow chart of a method for forming shielding structures for semiconductor packages, according to certain embodiments.

FIGS. 3A-3D illustrate a process flow for forming a sheet of shielding material, according to certain embodiments.

FIGS. 4A and 4B illustrate a sheet of shielding material, according to certain embodiments.

FIGS. 5A-5D illustrate shielding structures, according to certain embodiments.

FIGS. 6A and 6B illustrate a shielding structure being inserted into a device, according to certain embodiments.

FIG. 7 illustrates a flowchart of a method for forming a shielding structure on a device, according to certain embodiments.

FIGS. 8A-8D illustrate a process flow for forming a shielding structure on a device, according to certain embodiments.

FIG. 9 illustrates an exemplary computer system, in which various embodiments may be implemented.

### DETAILED DESCRIPTION

A number of system level and package level approaches have been adopted to shield components from internal and external electromagnetic interference (EMI). However, with increasing miniaturization, the demand for miniaturized shields offering equal or better isolation is crucial. Metal cans and metallized over-molds are currently the prevalent methods of EMI suppression for a package. Such approaches lead to thick shield structures and can only shield one package from others. As devices and systems such as advanced packages are scaled down further, more functionality (i.e., more components and/or electronic devices) may be integrated into a single package. As the number and density of electronic devices grow, the need for shielding some or all of the electronic devices in the package may also grow. For example, it may be desirable to shield components from one another in a single package.

A package may have several components that working in conjunction with one another. The components may perform various functions, components deliver power, sense certain signals, process the signals, or communicate data, etc. Some or all of the components may create electromagnetic radiation due to their functions, interfering with neighboring components as EMI. EMI may disturb a victim component, sensitive to EMI in a particular frequency range. For example, power components may switch at 1-100 MHz. The resulting harmonics may interfere with a radio frequency (RF) transceiver in the certain bands (e.g., LTE bands 2.4 GHZ). A processor that switches at 140 MHz may have a 13th harmonic at 1.82 GHz, which can overlap with the LTE Band III.

Other types of components may emit other types of EMI. For example, transmission lines may have associated timing clocks that switch at ranges from 100 MHz to 1 GHz (e.g., transmission lines for HDMI, USB, DDR, SERDES etc.). The EMI (or noise) created may interfere with a victim such as an antenna. The transmission lines may therefore need to be shielded with suitable encapsulation materials. Frequently, metamaterials are used to create electromagnetic bandgap isolation (EBG) structures to shield the transmission lines to reduce the effect of the emitted EMI. The victim may also to be shielded from receiving the EMI. However, in the example of an antenna, the shield must be designed such that basic antenna function is not affected. Shielding should, therefore, include trade-offs such that basic system functions are not affected. One way to accomplish this is by creating smart shielding materials that can selectively be tuned or reconfigured from the aggressor. Consumer electronics have omnidirectional antennas and can couple noise from all directions while mmWave antennas are directional. Shielding consumer antenna include strategies such as shielding from a particular direction by selectively manipulating the radiation pattern. EMI noise may also be intercepted by a hacker in proximity to deduce sensitive information about the system. This poses a major security threat as the hacker can even tamper with the system operation and retrieve sensitive information.

While a partitioned metallized over-mold shields may be one possible approach, the partitioned over-mold may not provide miniaturization. Most of these shields utilize thick metal layers for good EMI absorption loss and good mechanical stability. However, when integrating a shield into a package for the individual components, thinner shielding may be desirable, both for ease of manufacture/assembly and to allow for smaller packages with the same functionality. While it may be desirable to have the integrated shields be as thin as possible, the integrated shields must also provide the same performance (e.g., shielding effectiveness) as other shielding types.

One approach may be to integrate shields into a design of a package, where each shield is tuned to the specific requirements of the component to be shielded. For example, during a design process of a package, the shielding requirements for one or more components may be considered. A shield may then be created using 3D microfabrication process that is often used to realize microelectromechanical systems (MEMS) processes and/or micro assembly processes to include materials needed to appropriately shield each component. The shield may then be shaped and/or assembled, again using MEMS and/or micro assembly processes, to correspond to the component to be shielded. Then, during the manufacture of the package, the package may be designed with one or more trenches to receive the shield and secure the shield in place around the component to be shielded. The addition of the trenches may also allow more thermal protection to be provided to the device. For example, graphene or silver paste or other thermally-conducting paste may be inserted into the trenches to provide thermal shielding around more of the component to be shielded. The techniques and devices described herein may provide for integrated shielding of electronic devices in semiconductor devices, advanced packages, and other such systems. The integrated shielding may provide less expensive shielding and greater protection of components, overcoming some issues of more common shielding methods.

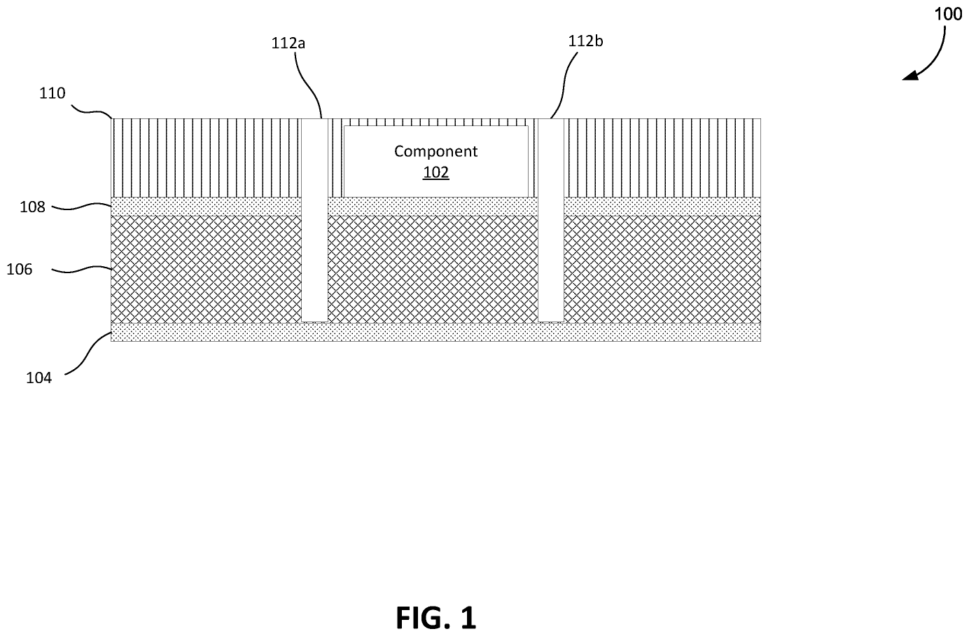

FIG. 1 illustrates a device 100 with a component 102 to be shielded, according to certain embodiments. The device 100 may be a semiconductor device or other such electronic device. The device 100 may additionally or alternatively be a part of a package, including multiple components and electronic device. The device 100 may include one or more layers such as a substrate 104, a first metal layer 106, first dielectric layer 108, a second metal layer 109, and a second dielectric layer 110. The substrate 104 may include silicon, gallium, polycrystalline silicon, aluminum nitride, or other suitable materials. The first metal layer 106 and second metal layer 109 may include titanium nitride, copper, tungsten, cobalt, and/or other suitable metals. The first and second dielectric layers 108 and 110 may include a metal oxide, ceramic, polymers, or other suitable dielectric materials. It should be understood that the layers shown and described in FIG. 1 are merely examples; the device 100 may include more or less layers, and/or include different materials in any of the layers. One of ordinary skill in the art would recognize many different possibilities and configurations.

The device 100 may also include trenches 112a-b. The trenches 112a-b may be placed near the component 102 in order to accept a shielding structure. The trenches 112a-b may extend through all or some of the layers of the device 100. In some embodiments, the trenches 112a-b may be formed during a deposition process(es) used to manufacture the device 100. For example, the layers of the device 100 may be deposited via atomic layer deposition (ALD), chemical vapor deposition (CVD), physical vapor deposition (PVD), or other such deposition techniques. The trenches 112a-b may then be formed using a mask or other such method to prevent the deposition of materials in within the trenches 112a-b. Additionally or alternatively, the trenches 112a-b may be formed via an etching process after the layers of the trenches 112a-b are formed. The trenches 112a-b may also be formed via laser cutting or other ablation techniques. In some embodiments, the trenches 112a-b may be coated in a magnetic material or film.

The component 102 may be an aggressor, emitting EMI that affects other components included in the device 100, or may be a victim, effected by EMI (or other EM signals) emitted by the other components. For example, the component 102 may include an antenna, affected by one or more other components (e.g., a processor) generating EMI somewhere else on the device 100. In another example, the component 102 may be a via or other pathway, carrying a signal that radiates EMI. The EMI may affect other components on the device 100. In any case, the potential effects of EMI associated with the component 102 may be known or expected prior to operation. Thus, a shielding structure may be designed specifically for the component 102. The shielding structure may then be integrated into the component 102 during the manufacturing process, shielding the component 102 during operation.

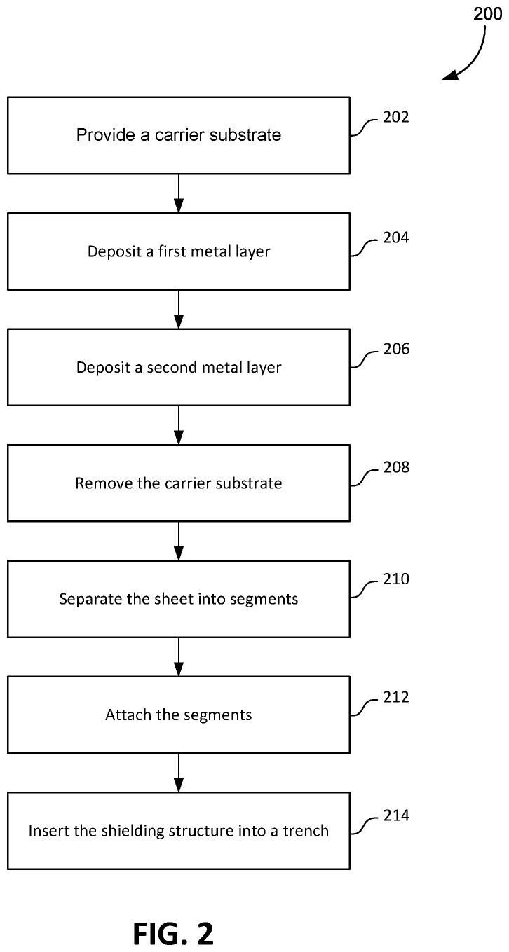

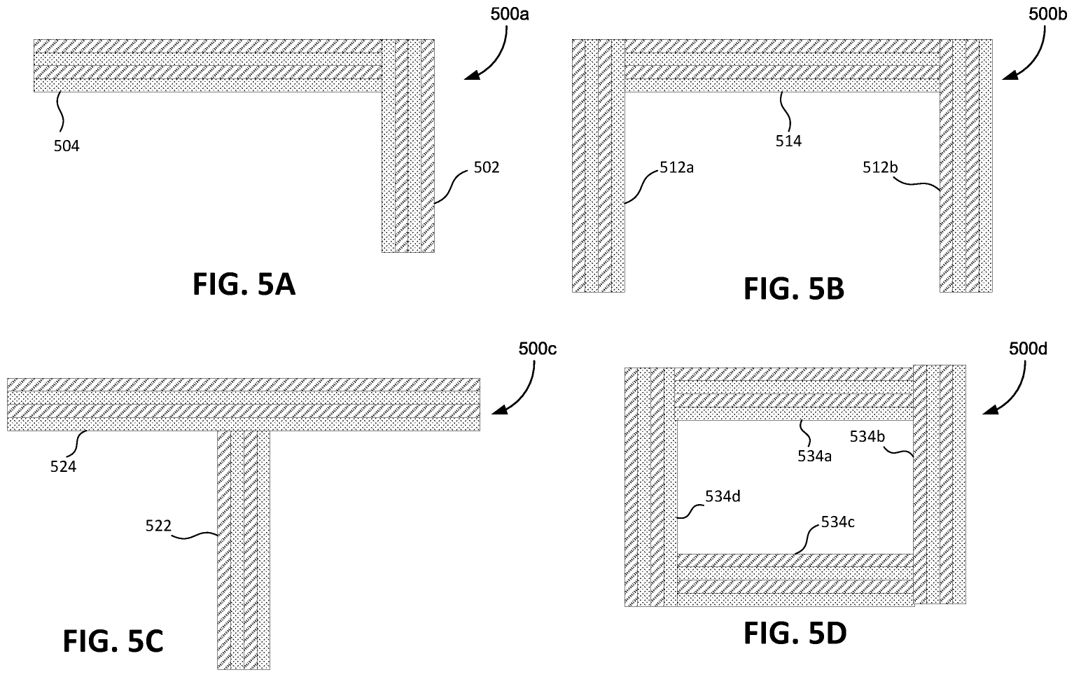

FIG. 2 illustrates a flow chart of a method 200 for forming shielding structures for semiconductor packages, according to certain embodiments. The method 200 may be performed to from any of the devices and structures described herein, such as the shielding structures described in relation to FIGS. 5A-5D. In some embodiments, the steps of the method 200 may be performed in a different order than that shown in FIG. 2, and/or some steps may be combined. Some steps of the method 200 may be skipped altogether.

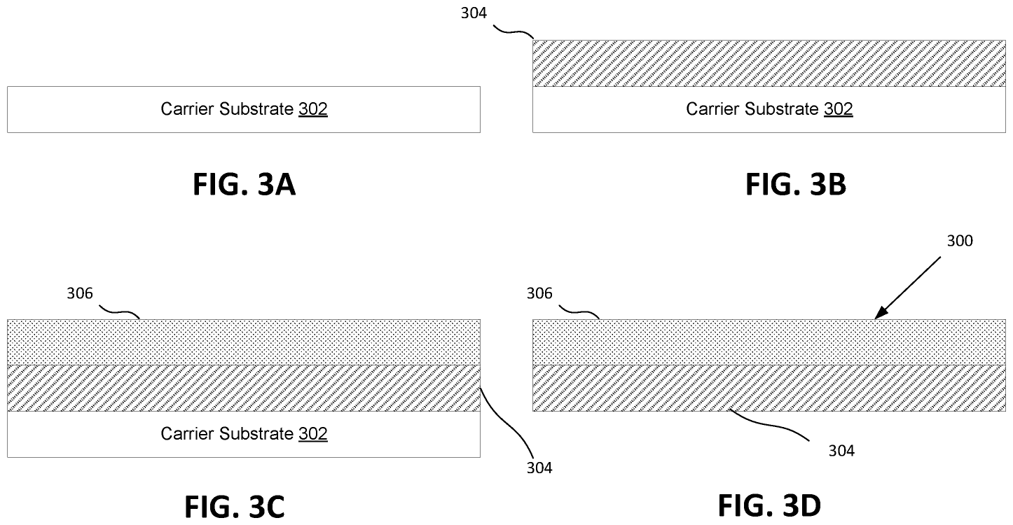

At step 202, the method 200 may include providing a carrier substrate 302, as shown in FIG. 3A. The carrier substrate 302 may be a temporary substrate, providing a surface on which to deposit one or more material used to create the sheet 300. The carrier substrate 302 may be disposable, used once to manufacture the sheet 300, or may be reusable such that multiple sheets of shielding material may be manufactured on the carrier substrate 302.

At step 204, the method 200 may include depositing, a first metal layer 304 on the carrier substrate 302, as shown in FIG. 3B. Additionally or alternatively, the first metal layer 304. may be formed using a MEMS process and/or a microassembly process. The first metal layer 304 may include copper, nickel, iron, cobalt, or other suitable metals. The first metal layer 304 may be deposited to a first thickness such as about 1 μm, about 2 μm, about 3 μm, and/or about 5 μm. The first thickness of the first metal layer 304 may be based on the desired shielding characteristics of a shielding structure to be formed from the sheet 300. For example, the first thickness may be determined based on a frequency of expected EMI, a mechanical constraint associated with a device (e.g., the device 100), a thermal shielding requirement, or other such requirement.

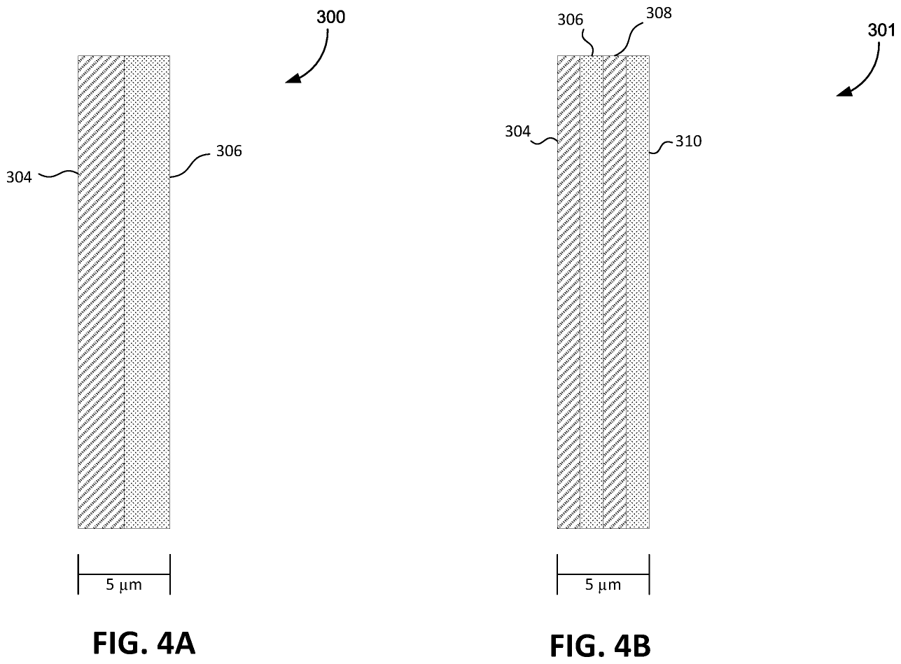

The first thickness may also be determined based at least in part on the overall thickness of the shielding structure and/or the number of metal layers included in the sheet 300. For example, in FIG. 4A, the sheet 300 may include two metal layers. The overall thickness of the sheet 300 in FIG. 4A may be 5 μm. The first thickness may therefore be 2.5 μm. In other embodiments, the first thickness may be within a range of 0.5 μm to 4.5 μm, inclusive. In relation to FIG. 4B, the sheet 301 may include four metal layers, with an overall thickness of 5 μm. In some embodiments, the total thickness of the sheet 300 may be about 5 μm to about 100 μm. The first thickness of the first metal layer 304 may therefore be 1.25 μm, if all four metal layers are of equal thickness. In some embodiments, each metal layer may have a different thickness based upon the shielding properties desired. In some embodiments, the sheet 300 may include a single metal layer (e.g., copper, nickel, cobalt, zirconia, etc.).

At step 206, the method 200 may include depositing a second metal layer 306, as is shown in FIG. 3B. Additionally or alternatively, the second metal layer 306 may be formed using a MEMS process and/or a microassembly process. The second metal layer 306 may include copper, nickel, iron, cobalt, or other suitable metals. The second metal layer 306 may include a different metal than that of the first metal layer 304 or may include the same metal. The second metal layer 306 may be deposited to a second thickness such as about 1 μm, about 2 μm, about 3 μm, and/or about 5 μm. The second thickness of the second metal layer 306 may be based on the desired shielding characteristics of a shielding structure to be formed from the sheet 300. For example, the second thickness may be determined based on a frequency of expected EMI, a mechanical constraint associated with a device (e.g., the device 100), a thermal shielding requirement, or other such requirement.

The second thickness may also be determined based at least in part on the overall thickness of the shielding structure and/or the number of metal layers included in the sheet 300. For example, in FIG. 4A, the sheet 300 may include two metal layers. The overall thickness of the sheet 300 in FIG. 4A may be 5 μm. The second thickness may therefore be 2.5 μm. In other embodiments, the second thickness may be within a range of 0.5 μm to 4.5 μm, inclusive. In relation to FIG. 4B, the sheet 301 may include four metal layers, with an overall thickness of 5 μm. The second thickness of the second metal layer 304 may therefore be 1.25 μm, if all four metal layers are of equal thickness. In some embodiments, each metal layer may have a different thickness based upon the shielding properties desired.

In relation to FIG. 4B, the method 200 may further include depositing a third metal layer 408 and/or a fourth metal layer 410. The third metal layer 408 and fourth metal layer 410 may include the same or different metals as compared to the first metal later 404 and the second metal layer 406. For example, the sheet 401 may include alternating layers such that the first metal layer 404 and the third metal layer 408 include a first metal, and the second metal layer 406 and the fourth metal layer 410 include a second metal. Although FIGS. 4A and 4B illustrate the sheet 300 having two and four metal layers, respectively, the sheet 300 may include any number of metal layers. For example, the sheet 300 may include 3 layers, 5 layers, 6 layers, etc. A thickness of each layer may be determined considering the overall thickness of the sheet 300.

Furthermore, each layer may be a magnetic or a nonmagnetic conductor. A sheet of shielding material 300 may include 5 layers, for example, with 2 magnetic conducting layers and 3 nonmagnetic conducting layers. A sheet 300 with 4 layers may include 2 nonmagnetic conducting layers and 2 magnetic conducting layers.

At step 208, the method 200 may include removing the carrier substrate 302, such that the sheet 300 is formed from the first metal layer 304 and the second metal layer 306, as shown in FIG. 2D. The carrier substrate 302 may be removed using a MEMS process, a micro assembly process, an etching process, ablation, or any other suitable method. Although FIG. 3D only shows the sheet 300 as having two metal layers, any number of metal layers may be present (e.g., four metal layers as shown in FIG. 4B).

In some embodiments, the sheet 300 (and/or the sheet 301) may be formed via a semi-additive plating process, In other embodiments, the sheet 300 may include a prefabricated copper structure. The prefabricated copper structure may then be coated with graphene via CVD. The sheet 300 may also be coated in an adhesive such as a B-staged epoxy, to assist in a final assembly process (as described below).

At step 210, the method 200 may include separating the sheet 300 into two or more segments. As shown in FIGS. 5A-5D, the sheet 300 may be separated into any number of segments. The sheet 300 may be separated via a 3D microfabrication process, a microassembly process, by laser or mechanical cutting techniques, and/or by any other suitable method or process. The sheet 300 may be separated into a number of segments according to a desired shape of a shielding structure. For example, an L-shaped shielding structure may require a top segment and a bottom segment. A U-shaped shielding structure may require a first vertical segment, a second vertical segment, and a horizontal segment. Other configuration may require any number of segments. One of ordinary skill in the art would recognize many different possibilities.

At step 212, the method 200 may include attaching each of the two or more segments to form a shielding structure. The two or more segments may be attached via a MEMS process, a microassembly process, an adhesive, a soldering process, welding process, and/or any other suitable process. The two or more segments may be attached in orthogonal planes in order to create a shielding structure of the desired shape. In FIG. 5A, a bottom segment 502 and a top segment 504 may be joined to form an L-shaped shielding structure 500a. The L-shaped shielding structure 500a may be configured to shield a component on two orthogonal sides (e.g., a top and a lateral side). The bottom segment 502 may be configured to be inserted into a trench in a device, such as the trench 112a in FIG. 1.

In FIG. 5B, a first vertical segment 512a and a second vertical segment 512b may be attached to a horizontal segment 514 to form a U-shaped shielding structure 500b. The U-shaped shielding structure 500b may be configured to shield a component on three sides, (e.g., two lateral sides and a top side). One or both of the vertical segments 512a-b may be configured to be inserted into trenches in a substrate, such as the trenches 112a-b in FIG. 1.

In FIG. 5C, a vertical segment 522 may be attached to a horizontal segment 524 to form a T-shaped shielding structure 500c. The T-shaped shielding structure 500c may be configured to shield one or more components on a lateral side and/or a top side. In some embodiments, the vertical segment 522 may be configured to be inserted into a trench in a substrate. Additionally or alternatively, a portion of the horizontal segment 524 may be configured to be inserted into a trench in a substrate. The vertical segment 522 may extend across opposite sides of the trench.

In FIG. 5D, a first lateral side 534a, a second lateral side 534b, a third lateral side 534c, and a fourth lateral side 534d may be attached to form a box-shaped shielding structure 500d. each of the lateral sides 534a-d may be configured to be inserted into a corresponding trench in a substrate. Thus, the box-shaped shielding structure 500d may shield a component on four later sides (e.g., from other components in the same device or package). In some embodiments, a top sheet may also be attached to the lateral sides 534a-d, shielding the component from the top of the component.

The shielding structures shown and described in FIGS. 5A-5D should be understood to just be examples of possible shielding structures. According to the methods and processes described herein, any number of shapes with any number of segments may be designed (e.g, triangular, pentagonal, cubic, etc.). One of ordinary skill in the art would recognize may different possibilities and configurations.

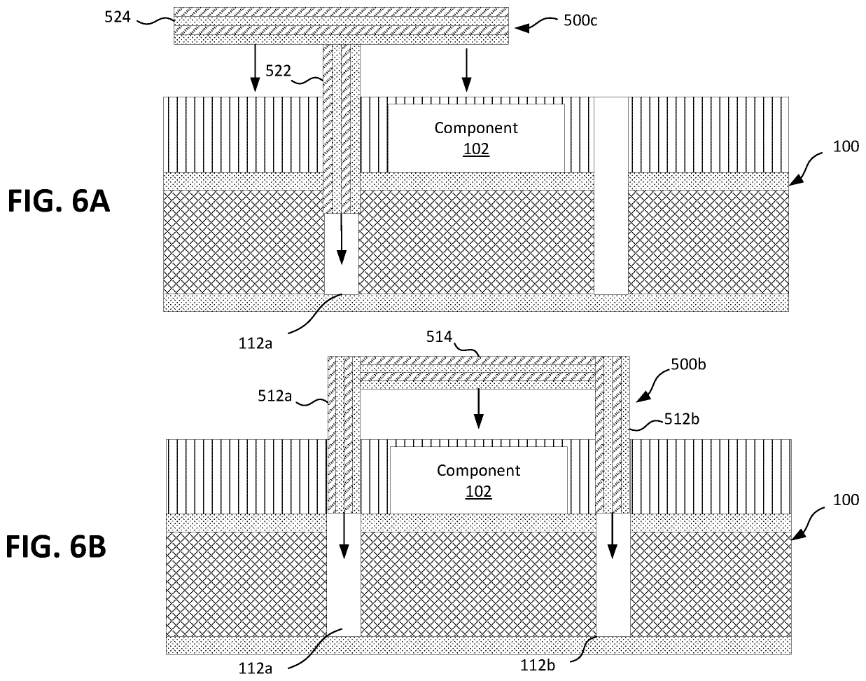

At step 214, the method 200 may include inserting the shielding structure into a trench disposed in a substrate of an electronic device. The shielding structure may be inserted into the substrate of the electronic device using a MEMS process, microassembly, or any other suitable process. The shielding structure may be placed utilizing a pick and place tool or other precision assembly tool. Turning to FIG. 6A, the T-shaped shielding structure 500c may be inserted into the device 100 to shield the component 102. Although not pictured, the device 100 may include a second component, also to be shielded by the T-shaped shielding structure 500c.

The vertical segment 522 may be inserted in the trench 112a in the device 100. The trench 112a may extend through one or more metal layers. The trench 112a may be at least partially filled with a paste including silver and/or another metal, graphene, and adhesive, and/or other suitable materials. The paste may be a solder paste. The paste may be a conducting and/or metal paste, and at least partially provide an electrical connection between the vertical segment 522 and one or more of the metal layers of the device 100. For example, the paste may adhere the vertical segment 522 in the trench 112a and provide an electrical connection to ground, allowing the T-shaped shielding structure to be electrically isolated from other components within the device 100. Additionally or alternatively, the trench 112a may include an epoxy, such as B-staged epoxy. The trench 112a may include a magnetic layer on one or more walls of the trench. The magnetic layer may extend from a surface of the device 100 to the substrate.

At least a portion of the horizontal segment 524 may extend over the component 102. In traditional shielding techniques, a shielding structure may be created by depositing shielding material on a surface of the component (e.g., the component 102). Therefore, there may be no way of providing additional thermal protection for (or from) the component 102. However, because the T-shaped shielding structure 500c is pre-assembled and then inserted into the trench 112a, thermal protection such as graphene paste may be applied to the top side of the component 102 prior to inserting the T-shaped shielding structure into the device 100.

In FIG. 6B, the U-shaped shielding structure 500b may be inserted into the trenches 112a-b of the device 100. The first and second vertical segments 512a-b may both be inserted into the respective trenches 112a-b and extend through one or more metal layers (and/or other layer) of the device 100. As described in FIG. 6A, the trenches 112a-b may be filled with epoxy or paste. The U-shaped shielding structure 500b may be electrically connected to one or more of the metal layers within the device 100 (e.g., the ground). Additionally, thermal paste may be disposed between the horizontal segment 514 and the component 102.

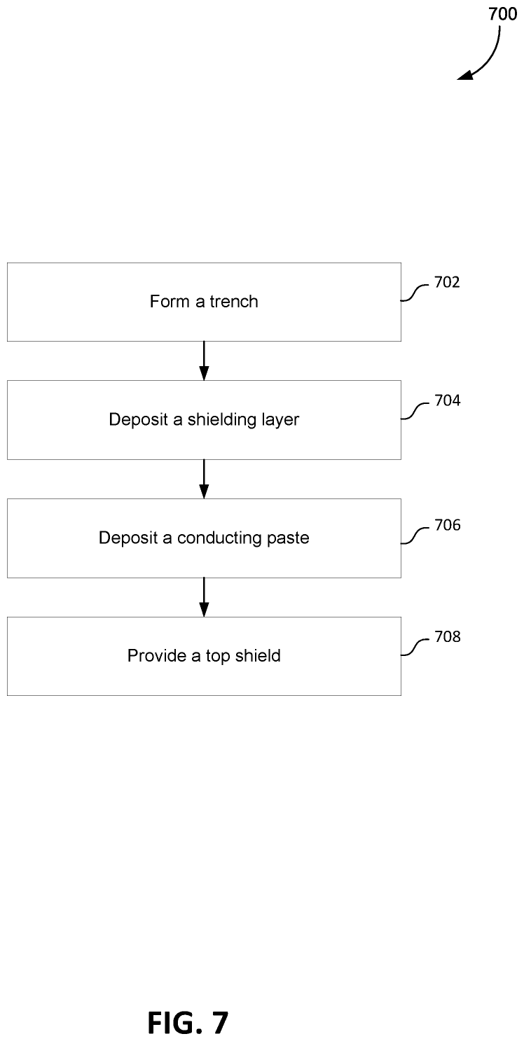

FIG. 7 illustrates a flowchart of a method 700 for forming a shielding structure on a device, according to certain embodiments. The method 700 may be performed in addition to or instead of the method 200. In some embodiments, the steps of the method 700 may be performed in a different order than that shown in FIG. 7, and/or some steps may be combined. Some steps of the method 200 may be skipped altogether. The method 700 may be performed on a device, such as the device 100, where the device includes trenches 112a-b through the substrate and/or other layers of the device 100.

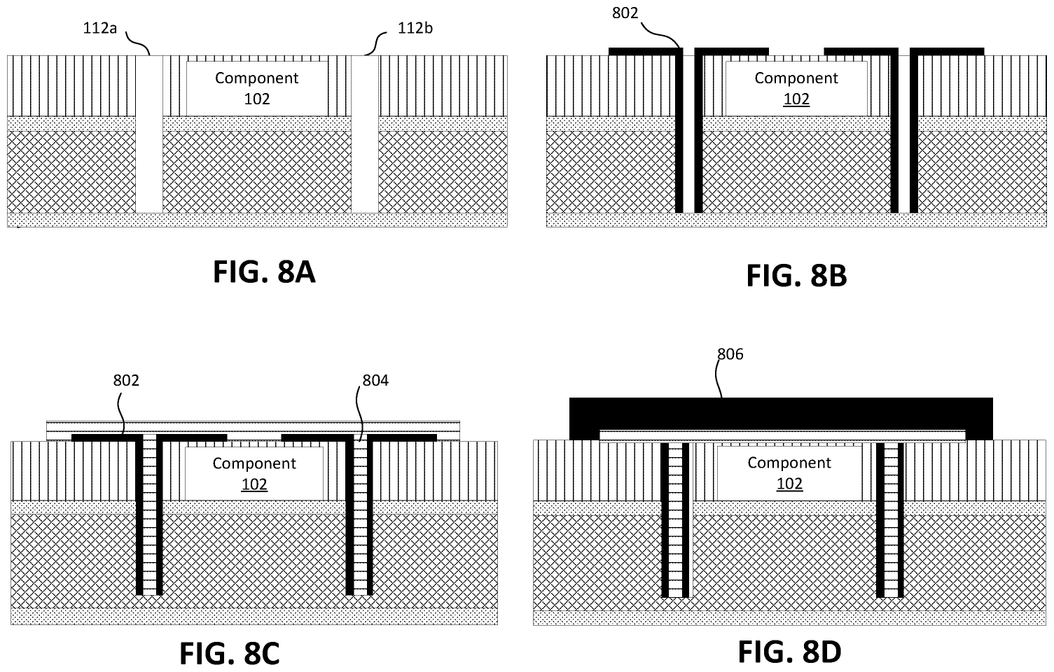

At step 702, the method 700 may include forming the trenches 112a-b in the device 100, according to a shielding requirement of the component 102, as shown in FIG. 8A. The trenches 112a-b may be formed via laser drilling, mechanical drilling, an etching process, ablation, or any other suitable method. The trenches 112a-b may be positioned adjacent to the component 102 in order to provide integrated shielding to the component 102. The shielding requirement of the component 102 may allow a very thin shield structure (e.g., about 1 micron to about 50 microns).

At step 704, the method 700 may include depositing a shielding layer 802 on at least some of the device and within the trenches 112a-b, as shown in FIG. 8B. Depositing the shielding layer may include providing a seed layer and sputtering or otherwise depositing one or more metals on the seed layer. The shielding layer 802 may include a total thickness of about 1 μm to about 50 μm. The shielding layer 802 may include silver, copper, nickel, iron, cobalt, or any other suitable material. The shielding layer 802 may further include layers of different metals, similar to the sheet 300 in FIGS. 3A-d.

At step 706, the method may include providing a conducting paste 804 within the trenches 112a-b such that the trenches 112a-b are substantially filled, as is illustrated in FIG. 8C. The conducting paste 804 may include silver, graphene, or any other suitable material. In some embodiments, the conducting paste 804 enables the shielding layer 802 to be electrically connected to one or more layers of the device 100 (e.g., to ground the shielding layer 802). The conducting paste 804 may also include thermal shielding (or conductive) properties, aiding in thermal management of the component 102. The conducting paste 804 may therefore also be provided above the component 102, providing thermal shielding to the top side of the component.

At step 708, the method may include providing a top shield 806 to the top of the component, as shown in FIG. 8D. The top shield 806 may be preassembled, using a process such as is described in relation to FIG. 2. The top shield 806 may include similar layers and materials as the shielding layer 802. The top shield 806 may be attached to the shielding layer 802 via soldering, welding, adhesive, or other suitable methods. The top shield 806 may be electrically connected to the shielding layer 802 via the attachment and/or the conducting paste 804. By shielding the component 102 via the method 700, thin shielding may be formed within the trenches 112a-b, while more robust shielding may be provided to the top of the component 102 from the top shield 806. Furthermore, because the top shield 806 is preassembled and then installed on the component 102, thermal or conducting paste or other films may be provided on top of the component 102.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user or may be done automatically by a computer system without human intervention where any determinations are made by a processor. Furthermore, some embodiments of each of the methods described herein may be implemented as a set of instructions stored on a tangible, non-transitory storage medium to form a tangible software product.

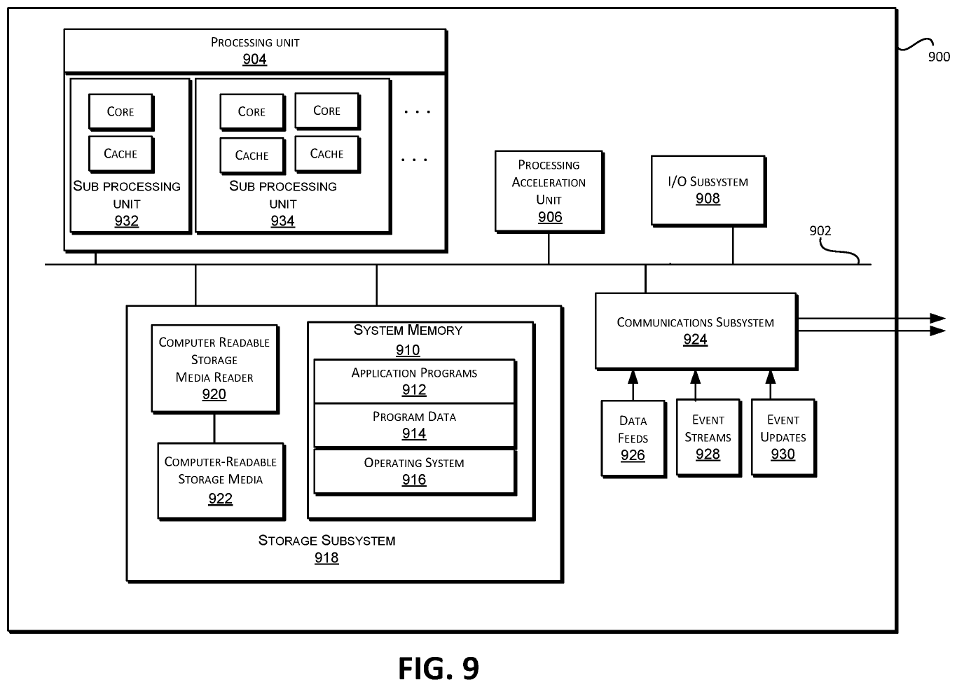

FIG. 9 illustrates an exemplary computer system 900, in which various embodiments may be implemented. The system 900 may be used to implement any of the computer systems described above. As shown in the figure, computer system 900 includes a processing unit 904 that communicates with a number of peripheral subsystems via a bus subsystem 902. These peripheral subsystems may include a processing acceleration unit 906, an I/O subsystem 908, a storage subsystem 918 and a communications subsystem 924. Storage subsystem 918 includes tangible computer-readable storage media 922 and a system memory 910.

Bus subsystem 902 provides a mechanism for letting the various components and subsystems of computer system 900 communicate with each other as intended. Although bus subsystem 902 is shown schematically as a single bus, alternative embodiments of the bus subsystem may utilize multiple buses. Bus subsystem 902 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 904, which can be implemented as one or more integrated circuits (e.g., a conventional microprocessor or microcontroller), controls the operation of computer system 900. One or more processors may be included in processing unit 904. These processors may include single core or multicore processors. In certain embodiments, processing unit 904 may be implemented as one or more independent processing units 932 and/or 934 with single or multicore processors included in each processing unit. In other embodiments, processing unit 904 may also be implemented as a quad-core processing unit formed by integrating two dual-core processors into a single chip.

In various embodiments, processing unit 904 can execute a variety of programs in response to program code and can maintain multiple concurrently executing programs or processes. At any given time, some or all of the program code to be executed can be resident in processor(s) 904 and/or in storage subsystem 918. Through suitable programming, processor(s) 904 can provide various functionalities described above. Computer system 900 may additionally include a processing acceleration unit 906, which can include a digital signal processor (DSP), a special-purpose processor, and/or the like.

I/O subsystem 908 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices that enables users to control and interact with an input device through a natural user interface using gestures and spoken commands. Additionally, user interface input devices may include voice recognition sensing devices that enable users to interact with voice recognition systems through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader, 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 900 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 900 may comprise a storage subsystem 918 that comprises software elements, shown as being currently located within a system memory 910. System memory 910 may store program instructions that are loadable and executable on processing unit 904, as well as data generated during the execution of these programs.

Depending on the configuration and type of computer system 900, system memory 910 may be volatile (such as random access memory (RAM)) and/or non-volatile (such as read-only memory (ROM), flash memory, etc.). The RAM typically contains data and/or program modules that are immediately accessible to and/or presently being operated and executed by processing unit 904. In some implementations, system memory 910 may include multiple different types of memory, such as static random access memory (SRAM) or dynamic random access memory (DRAM). In some implementations, a basic input/output system (BIOS), containing the basic routines that help to transfer information between elements within computer system 900, such as during start-up, may typically be stored in the ROM. By way of example, and not limitation, system memory 910 also illustrates application programs 912, which may include client applications, Web browsers, mid-tier applications, relational database management systems (RDBMS), etc., program data 914, and an operating system 916.

Storage subsystem 918 may also provide a tangible computer-readable storage medium for storing the basic programming and data constructs that provide the functionality of some embodiments. Software (programs, code modules, instructions) that when executed by a processor provide the functionality described above may be stored in storage subsystem 918. These software modules or instructions may be executed by processing unit 904. Storage subsystem 918 may also provide a repository for storing data used in accordance with some embodiments.

Storage subsystem 900 may also include a computer-readable storage media reader 920 that can further be connected to computer-readable storage media 922. Together and, optionally, in combination with system memory 910, computer-readable storage media 922 may comprehensively represent remote, local, fixed, and/or removable storage devices plus storage media for temporarily and/or more permanently containing, storing, transmitting, and retrieving computer-readable information.

Computer-readable storage media 922 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 900.

By way of example, computer-readable storage media 922 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD or other optical media. Computer-readable storage media 922 may include, but is not limited to, flash memory cards, universal serial bus (USB) flash drives, secure digital (SD) cards, DVD disks, digital video tape, and the like. Computer-readable storage media 922 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 900.

Communications subsystem 924 provides an interface to other computer systems and networks. Communications subsystem 924 serves as an interface for receiving data from and transmitting data to other systems from computer system 900. For example, communications subsystem 924 may enable computer system 900 to connect to one or more devices via the Internet. In some embodiments communications subsystem 924 can include radio frequency (RF) transceiver components for accessing wireless voice and/or data networks (e.g., using cellular telephone technology, advanced data network technology, such as 3G, 4G, 5G, or EDGE (enhanced data rates for global evolution), WiFi (IEEE 802.9 family standards, or other mobile communication technologies, or any combination thereof), global positioning system (GPS) receiver components, and/or other components. In some embodiments communications subsystem 924 can provide wired network connectivity (e.g., Ethernet) in addition to or instead of a wireless interface.

In some embodiments, communications subsystem 924 may also receive input communication in the form of structured and/or unstructured data feeds 926, event streams 928, event updates 930, and the like on behalf of one or more users who may use computer system 900.

By way of example, communications subsystem 924 may be configured to receive data feeds 926 in real-time from users of social networks and/or other communication services, web feeds such as Rich Site Summary (RSS) feeds, and/or real-time updates from one or more third party information sources.

Additionally, communications subsystem 924 may also be configured to receive data in the form of continuous data streams, which may include event streams 928 of real-time events and/or event updates 930, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 924 may also be configured to output the structured and/or unstructured data feeds 926, event streams 928, event updates 930, and the like to one or more databases that may be in communication with one or more streaming data source computers coupled to computer system 900.

Due to the ever-changing nature of computers and networks, the description of computer system 900 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMS, EEPROMs, magnetic or optical cards, flash memory, or other types of machine-readable mediums suitable for storing electronic instructions. Alternatively, the methods may be performed by a combination of hardware and software.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

What is claimed is:

1. A semiconductor device, comprising:
a substrate comprising at least one trench;
a component, wherein the component requires shielding from electromagnetic signals; and
a shielding structure inserted in the at least one trench.

2. The semiconductor device of claim 1, wherein the shielding structure shields the component from electromagnetic signals.

3. The semiconductor device of claim 1, wherein the shielding structure extends through the trench and is electrically connected to a ground of the semiconductor device.

4. The semiconductor device of claim 3, wherein the shielding structure is bonded to the ground using a solder paste, a metal paste, or a silver paste.

5. The semiconductor device of claim 1, wherein the shielding structure comprises a single metal layer, the single metal layer comprising at least one of copper, nickel, iron, cobalt, and silver.

6. The semiconductor device of claim 1, wherein the shielding structure comprises magnetic conducting layers and nonmagnetic conducting layers.

7. The semiconductor device of claim 6, wherein the shielding structure comprises 2 nonmagnetic conducting layers and 2 magnetic conducting layers.

8. The semiconductor device of claim 6, wherein the shielding structure comprises 2 nonmagnetic conducting layers and 3 magnetic conducting layers or comprises 3 nonmagnetic conducting layers and 2 magnetic conducting layers.

9. The semiconductor device of claim 1, wherein the total thickness of the shielding structure is about 5 microns.

10. The semiconductor device of claim 1, wherein the shielding structure comprises two or more metal layers, each of the two or more metal layers comprising at least one of copper, nickel, iron, cobalt, and silver.

11. The semiconductor device of claim 1, wherein the shielding structure comprises a T-shape, wherein a bottom segment of the shielding structure is inserted into the trench, and a vertical segment of the shielding structure extends on opposite sides of the trench.

12. A shielding structure for a semiconductor device, the shielding component comprising:
a first segment formed from a first set of layers comprising a first metal and a second metal; and
a second segment formed from a second set of layers comprising the first metal and the second metal, the second segment orthogonal to the first segment, wherein the second segment is configured to be inserted into a trench in a substrate of the semiconductor device.

13. The shielding structure of claim 12, wherein the trench comprises a magnetic material on one or more walls of the trench, the magnetic material extending from a surface of the substrate to a metal layer of the semiconductor device.

14. The shielding structure of claim 12, wherein the first segment is configured to shield an electronic device from electromagnetic interference from a first direction, and the second segment is configured to shield an electronic device from electromagnetic interference from a second direction.

15. A method of forming shielding structures for semiconductor packages, comprising:
providing a carrier substrate;
depositing a first metal layer on the carrier substrate to a first thickness;
depositing a second metal layer on the first metal layer to a second thickness;
removing the carrier substrate from the first metal layer to form a sheet of shielding material;
separating the sheet of shielding material into two or more segments;
attaching each of the two or more segments in to form a shielding structure; and
inserting the shielding structure into a trench disposed in a substrate of a semiconductor package.

16. The method of claim 15, wherein the first thickness and the second thickness are about 2 micrometers to about 5 micrometers.

17. The method of claim 15, wherein the first thickness and the second thickness form a total thickness of between about 5 and about 50 micrometers.

18. The method of claim 15, wherein prior to inserting the shielding structure, the trench disposed in the substrate of the semiconductor package is filled with a conducting paste comprising silver and/or graphene.

19. The method of claim 16, wherein the shielding structure comprises a U-shape wherein at least one vertical segment is inserted into the trench of the substrate.

20. The method of claim 16, wherein the shielding structure comprises a L-shape wherein at least one vertical segment is inserted into the trench of the substrate.
